(19) United States
(12) Patent Application Publication
(10) Pub. No.: US 2019/0265795 A1
(43) Pub. Date: Aug. 29, 2019

(54) VIBRATION GENERATING DEVICE AND ELECTRONIC EQUIPMENT FOR NON-ACOUSTIC APPLICATIONS

(71) Applicant: TAIYO YUDEN CO., LTD., Tokyo (JP)

(72) Inventors: Shigeo ISHII, Takasaki-shi (JP); Takashi TOMITA, Takasaki-shi (JP); Hiroshi HAMADA, Takasaki-shi (JP); Fumihisa ITO, Takasaki-shi (JP); Yukihiro MATSUI, Takasaki-shi (JP)

(21) Appl. No.: 16/276,472

(22) Filed: Feb. 14, 2019

(30) Foreign Application Priority Data
Feb. 26, 2018 (JP) 2018-032402

(51) Int. Cl. G06F 3/01; B06B 1/06; H01L 41/053

(52) U.S. Cl. CPC G06F 3/016; B06B 1/0603; H01L 41/053; B06B 1/0666; B06B 1/0648

(57) ABSTRACT

A vibration generating device 90 for non-acoustic applications, includes: a piezoelectric element 11; a diaphragm 82 attached to the piezoelectric element 11 on a first side in a first direction; and a first frame body 84 provided along an outer peripheral portion of the diaphragm 82 to transmit vibration of the diaphragm 82 to a vibration object member 60, wherein the first frame body 84 is connectable to the vibration object member 60 in such a manner that the first frame body 84, the diaphragm 82 and the vibration object member 60 form an enclosed space 64.

### TECHNICAL FIELD

The present invention relates to a vibration generating device and an electronic equipment for non-acoustic applications.

### BACKGROUND ART

There is known a sound generating device such as a speaker obtained by receiving an acoustic generator including a piezoelectric element, a diaphragm and a frame body in a housing (for example, see Patent Literature 1).

However, in the sound generating device described in the above Patent Literature 1, it is not clear how the acoustic generator is received in the housing. Incidentally, the sound generating device is required to form an opening in the housing to radiate sound outside, so it is configured differing from a vibration generating device for non-acoustic applications.

### CITATION LIST

### Patent Literature

### [Patent Literature 1] Japanese Unexamined Patent Application Publication No. 2017-005537

### SUMMARY OF INVENTION

### Technical Problem

The present invention has been made in view of the above circumstances, and the present invention is to provide a vibration generating device and an electronic equipment suitable for non-acoustic applications.

### Solution to Problem

As a result of sensitive studies, the inventors have found that a vibration generating device is suitable for non-acoustic applications when a frame body, a diaphragm and a vibration object member are connected in such a manner as to form an enclosed space, and then the present invention has been accomplished.

A vibration generating device for non-acoustic applications according to a first aspect of the present invention includes: a piezoelectric element; a diaphragm attached to the piezoelectric element on a first side in a first direction; and a first frame body provided along an outer peripheral portion of the diaphragm to transmit vibration of the diaphragm to a vibration object member, wherein the first frame body is connectable to the vibration object member in such a manner that the first frame body, the diaphragm and the vibration object member form an enclosed space.

The first frame body may be provided along an outer peripheral portion on a surface at a second side of the diaphragm opposite to the first side in the first direction and may be connected to the vibration object member on the second side in the first direction.

The vibration generating device may further include a second frame body provided along an outer peripheral portion on the surface of the diaphragm on the first side in the first direction.

The vibration generating device may further include a joining member provided between the first frame body and the vibration object member, the joining member including a viscoelastic body.

The joining member may include a substrate layer and joining layers made of a viscoelastic body on both sides of the substrate layer in the first direction.

The joining member may be larger than the first frame body in a cross-sectional shape obtained by cutting along a plane having a normal vector in the first direction.

The vibration generating device may further include a vibration transmitting member provided in the enclosed space, the vibration transmitting member including at least one of a rubber material, a resin material and a silicone material and coming into contact with the diaphragm and the vibration object member in the first direction.

The piezoelectric element may have a bimorph structure or an unimorph structure.

An electronic equipment according to a second aspect of the present invention includes: the above-described vibration generating device; a vibration object member; and an electronic circuit for driving the vibration generating device. In this case, the vibration object member may be preferably a display panel.

### Advantageous Effects of Invention

In accordance with the present invention, it is possible to provide a vibration generating device and an electronic equipment suitable for non-acoustic applications.

### BRIEF DESCRIPTION OF DRAWINGS

FIG. 1A is a plan view schematically showing a vibration generating device according to a first embodiment of the present invention;

FIG. 1B is a cross-sectional view taken along a line A-A in FIG. 1A;

FIG. 2 is a schematic cross-sectional view showing a structure of a piezoelectric element as an example;

FIG. 3 is a cross-sectional view schematically showing a state that the vibration generating device according to the first embodiment is attached to a display panel;

FIG. 4 is an enlarged view showing a Q-portion in FIG. 3;

FIG. 5 is a plan view schematically showing an electronic equipment according to an embodiment of the present invention;

FIG. 6 is a cross-sectional view schematically showing a state that the vibration generating device according to a second embodiment is attached to a display panel;

FIG. 7 is a cross-sectional view schematically showing a state that the vibration generating device according to a third embodiment is attached to a display panel;

FIG. 8 is a cross-sectional view schematically showing a state that the vibration generating device according to a fourth embodiment is attached to a display panel; and

FIG. 9 is a cross-sectional view schematically showing a state that the vibration generating device according to a fifth embodiment is attached to a display panel.

### DESCRIPTION OF EMBODIMENTS

Hereinafter, a vibration generating device and an electronic equipment for non-acoustic applications according to embodiments of the present invention are described with reference to the accompanying drawings.

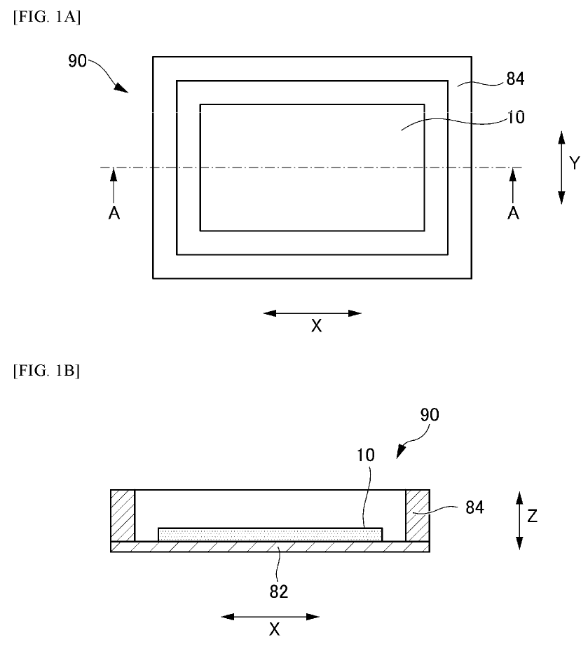

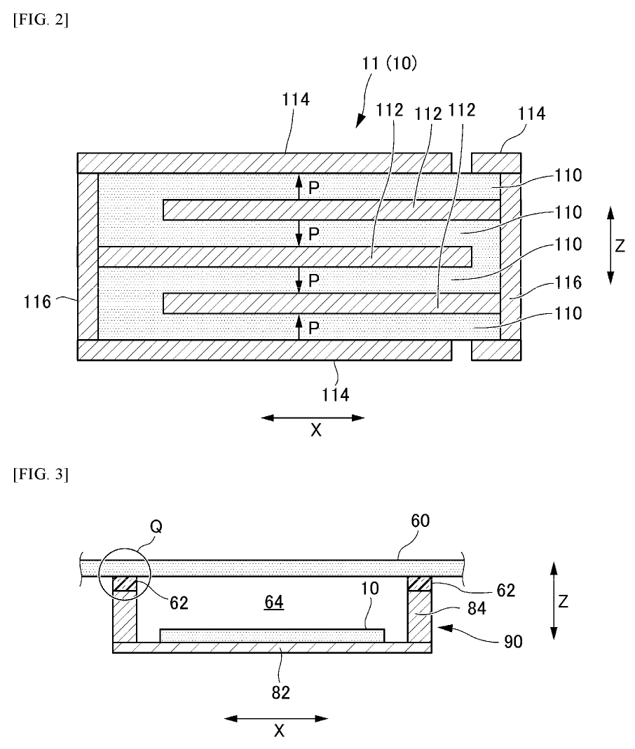

A vibration generating device for non-acoustic applications according to a first embodiment of the present invention is described with reference to FIGS. 1 to 5. “For non-acoustic applications” means that a device is not an acoustic device as represented by a speaker. The vibration generating device for non-acoustic applications is typically used for a tactile presentation device (for example, a force feedback device) that presents a tactile sense to a user through vibration or the like. FIG. 1A is a plan view schematically showing a vibration generating device 90 according to the first embodiment of the present invention. FIG. 1B is a cross-sectional view taken along a line A-A in FIG. 1A. FIG. 2 is a schematic cross-sectional view showing a structure of a piezoelectric element as an example.

In FIGS. 1A and 1B, X-, Y- and Z-directions are shown as three mutually orthogonal directions. In the following description, the Z-direction corresponds to a vertical direction for the sake of explanation. However, in fact, it may correspond to any direction in accordance with a state that the vibration generating device 90 is attached.

The vibration generating device 90 includes a piezoelectric actuator 10, a diaphragm 82 and a frame body 84 (as an example of a first frame body).

The piezoelectric actuator 10 may have any structure, and a structure as shown in FIG. 2 may be employed, for example. A piezoelectric element 11 of the piezoelectric actuator 10 is included in FIG. 2. The piezoelectric element 11 includes a piezoelectric layer 110 formed in four ceramics layers, an electrode laminate formed in three internal electrode layers 112 alternately laminated, surface electrodes 114 formed on one main surface (an upper surface) side and the other main surface (a lower surface) side of the electrode laminate, and side electrodes 116 formed on side surfaces of the internal electrode layers 112 which have end portions are alternately exposed. Note that the internal electrode layer 112, the surface electrode 114 and the side electrode 116 may be made of silver, a silver compound containing glass composed mainly of silica into silver, nickel or the like.

The piezoelectric layer 110 is formed including ceramics with piezoelectric properties. Examples of such ceramics may include not only lead zirconate titanate but also a lead-free piezoelectric material such as lithium niobate, lithium tantalate, Bi layered compound and tungsten bronze structure compound.

The piezoelectric element 11 according to the first embodiment has a rectangular shape in a top view, but it may have another shape (a polygonal shape, a circular shape or the like). In addition, the piezoelectric element 11 may have a unimorph structure or may have a bimorph structure as shown in FIG. 2. In the bimorph structure, as shown by P-arrows indicating polarization directions in FIG. 2, the polarization directions with respect to a direction of electric field generated when electric signals are applied to the surface electrode 114 are reversed toward one side and the other side in a thickness direction or the Z-direction. In the piezoelectric element 11 shown in FIG. 2, bending vibration is excited by applying electric signals to the surface electrode 114.

The piezoelectric actuator 10 may be obtained, for example, by preparing a slurry through mixing material powder of the piezoelectric layer 110 with an organic solvent, a binder, a plasticizer, a dispersant and the like at a predetermined ratio, making ceramic green sheets with a doctor blade method as known or the like, laminating the ceramic green sheets on the internal electrode and the external electrode, removing the binder at 500° C. in the atmosphere, and then integrally firing at 1,000° C. in the atmosphere. Not limited to the doctor blade method, the piezoelectric actuator 10 may also be obtained in another way, for example, by alternately printing and laminating a slurry containing material powder of the piezoelectric layer and a conductive paste containing an electrode material with a so-called slurry build method, and then integrally firing them.

The diaphragm 82 is a plate that generates vibration by driving the piezoelectric actuator 10. The diaphragm 82 has a rectangular shape, for example, but any shape is applicable. The diaphragm 82 may be made of a material with relatively high rigidity such as acrylic resin or glass. The piezoelectric element 11 is attached on an upper side (as an example of a first side) in a vertical direction or the Z-direction (as an example of a first direction) of the diaphragm 82. Specifically, a lower surface of the piezoelectric element 11 of the piezoelectric actuator 10 is attached to the upper surface of the diaphragm 82. The piezoelectric element 11 is attached to the diaphragm 82 via a joining member (not shown), for example. The joining member may be formed, for example, in a double-sided tape having adhesive layers adhered to both surfaces of a substrate such as a nonwoven fabric, or in an elastic adhesive. The piezoelectric actuator 10 may be attached on any position of the diaphragm 82, and, for example, it may be aligned with respect to a center of the diaphragm 82 or may be offset from the center of the diaphragm 82.

The frame body 84 extends along an outer peripheral portion of the diaphragm 82. The frame body 84 is fixed to the outer peripheral portion of the diaphragm 82. More specifically, the frame body 84 is fixed to the outer peripheral portion of the diaphragm 82 in a state that tension is applied to the diaphragm 82.

The frame body 84 functions as a support body to support the diaphragm 82. Further, the frame body 84 transmits vibration of the diaphragm 82 to a display panel 60. The frame body 84 may be made of metal such as stainless steel or resin, for example. It should be noted that a weight or the like may be further provided on the diaphragm 82.

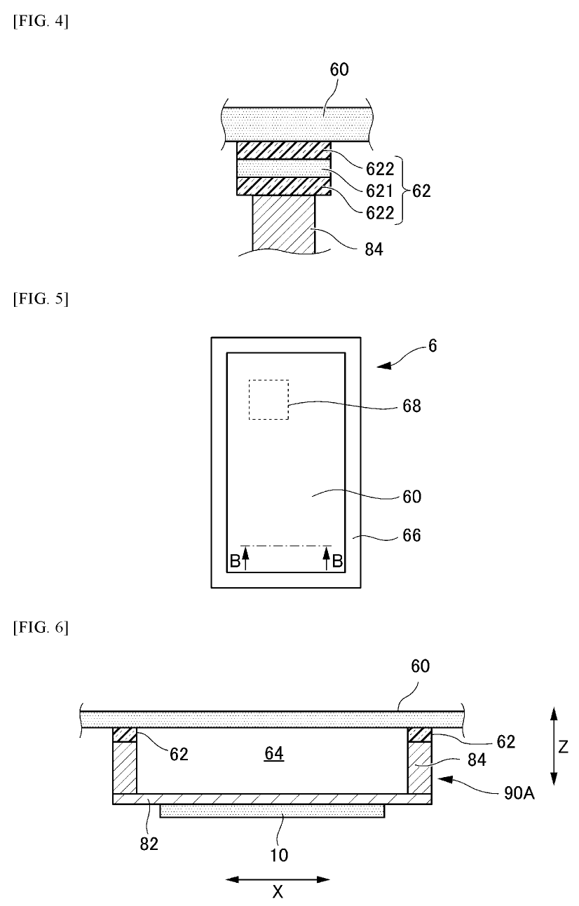

FIG. 3 is a cross-sectional view schematically showing a state that the vibration generating device 90 according to the first embodiment is attached to the display panel 60 (as an example of a vibration object member). FIG. 4 is an enlarged view showing a Q-portion in FIG. 3.

The vibration generation device 90 may function as a tactile presentation device (for example, a force feedback device) that presents a tactile sense to a user through vibration or the like via the display panel 60.

The display panel 60 may be, for example, a liquid crystal display panel or an organic EL (Electro Luminescence) display panel. A glass panel or the like with no display function may also be employed in place of the display panel 60.

As shown in FIG. 3, the vibration generating device 90 as described above with reference to FIGS. 1A and 1B is attached to the display panel 60 via a joining member 62. Specifically, the frame body 84 is connected to an inner surface of the display panel 60 via the joining member 62. As shown in FIG. 4, the joining member 62 preferably includes a substrate layer 621 and joining layers 622 on both sides of the substrate layer 621 in a vertical direction or the Z-direction. The substrate layer 621 may be made of a nonwoven fabric or the like. Each of the joining layers 622 may be made of an adhesive layer. In this case, the joining member 62 is formed in a double-sided tape. The joining layer 622 may be made of an epoxy resin, a thermoplastic urethane (as an example of a viscoelastic body) including a foam material, or the like. As a result, an enclosed space 64 surrounded by the display panel 60, the diaphragm 82 and the frame body 84 is obtained. In order to obtain the enclosed space 64, the vibrating plate 82 and others have no through hole.

In addition, the joining member 62 is preferably larger than the frame body 84 in a cross-section to be obtained by cutting along a plane (namely, a X-Y plane) having a normal vector in the Z-direction. For example, a dimension of the joining member 62 in the X-direction is larger than a dimension of the frame body 84 in the X-direction, as shown in FIG. 4. Similarly, although not shown, a dimension of the joining member 62 in the Y-direction may also be larger than a dimension of the frame body 84 in the Y-direction. Such dimensional relationship is realized by forming the joining member 62 so as to protrude from an upper surface of the frame body 84. Thereby, it is possible to enhance adhesiveness between the display panel 60 and the frame body 84.

When electric signals are applied to the surface electrode 114 of the piezoelectric element 11 of the vibration generating device 90, the piezoelectric element 11 performs bending vibration. As a result, the diaphragm 82 vibrates. That is, as described above, the diaphragm 82 vibrates together with the piezoelectric actuator 10 through vibration of the piezoelectric actuator 10. When the diaphragm 82 vibrates, vibration of the diaphragm 82 is transmitted to the display panel 60 via the frame body 84 and the joining member 62. That is, the frame body 84 and the joining member 62 transmit vibration of the diaphragm 82 to the display panel 60.

With the vibration generating device 90 according to the first embodiment, by attaching the vibration generating device 90 to the display panel 60 via the enclosed space 64, it is possible to efficiently transmit vibration to the display panel 60 as compared with a case where a through hole is formed in the diaphragm 82, for example.

Further, when the vibration generating device 90 is attached to the display panel 60 via the joining member 62 including a viscoelastic body, it is possible to make smoother vibration to be transmitted to the display panel 60 as compared with a case where the joining member 62 does not include a viscoelastic body.

Furthermore, with the vibration generating device 90 according to the first embodiment, since the piezoelectric actuator 10 is disposed inside the enclosed space 64, it is possible to make thinner the vibration generating device 90 as compared with a case where the piezoelectric actuator 10 is disposed outside the enclosed space 64 (see FIG. 6 described later).

Next, with reference to FIG. 5, an electronic equipment using the vibration generating device 90 is described. FIG. 3 as described above is a cross-sectional view taken along a line B-B in FIG. 5.

FIG. 5 is a plan view schematically showing the electronic equipment according to an embodiment of the present invention.

The electronic equipment 6 includes the piezoelectric actuator 10, the display panel 60, a housing 66, an electronic circuit 68, the diaphragm 82 and the frame body 84.

The electronic equipment 6 is configured in any type and, for example, it may be a mobile terminal such as a smartphone as shown in FIG. 5. Besides, the electronic equipment 6 may be a controller of a game machine, a wearable device, a tablet terminal, a portable music player or the like. Further, the electronic equipment 6 may be embodied as an in-vehicle electronic equipment. Furthermore, the electronic equipment 6 may be embodied as a household electronic equipment (a television, a vacuum cleaner, a washing machine, a refrigerator, a microwave oven, etc.).

The piezoelectric actuator 10 is as described above with reference to FIG. 2. The display panel 60 is as described above with reference to FIG. 3. The diaphragm 82 and the frame body 84 are as described above with reference to FIGS. 1A and 1B.

The housing 66 is a housing of the electronic equipment 6. Inside the housing 66, the electronic circuit 68 (schematically shown by a dotted line in FIG. 5), the vibration generating device 90 and the like are received.

The electronic circuit 68 is electrically connected to the piezoelectric actuator 10. The electronic circuit 68 applies electric signals for driving the piezoelectric actuator 10 to the piezoelectric actuator 10. The piezoelectric actuator 10 may be driven under control of a controller including the electronic circuit 68.

In a case where the piezoelectric element 11 has a bimorph structure, it is possible to make thinner the vibration generating device 90 and efficiently vibrate the diaphragm 82 with less energy. In addition, since the piezoelectric element 11 itself performs bending vibration, it is possible to reduce mechanical loss at a surface joined with the diaphragm 82.

Next, vibration generating devices according to other embodiments are described. In the description of other embodiments, the details of constituent elements that may be the same as the above-described first embodiment are omitted by assigning the same reference signs thereto.

FIG. 6 is a cross-sectional view schematically showing a state that a vibration generating device 90A according to a second embodiment is attached to the display panel 60 (as an example of a vibration object member).

The vibration generating device 90A according to the second embodiment is different from the vibration generating device 90 according to the above-described first embodiment in that the piezoelectric actuator 10 is provided on a surface at a side or a lower side (as an example on the first side) opposite to the diaphragm 82. Like the first embodiment as described above, the frame body 84 is provided on the outer periphery of a surface at an upper side (as an example of the second side) of the diaphragm 82, and the upper side is connected to the display panel 60.

Even with the vibration generating device 90A according to the second embodiment, it is possible to achieve the effects similar to those of the vibration generating device 90 according to the above-described first embodiment. Further, since the piezoelectric actuator 10 is not provided inside the enclosed space 64, it is possible to make easy wiring connection and increase volume of gas inside the enclosed space 64.

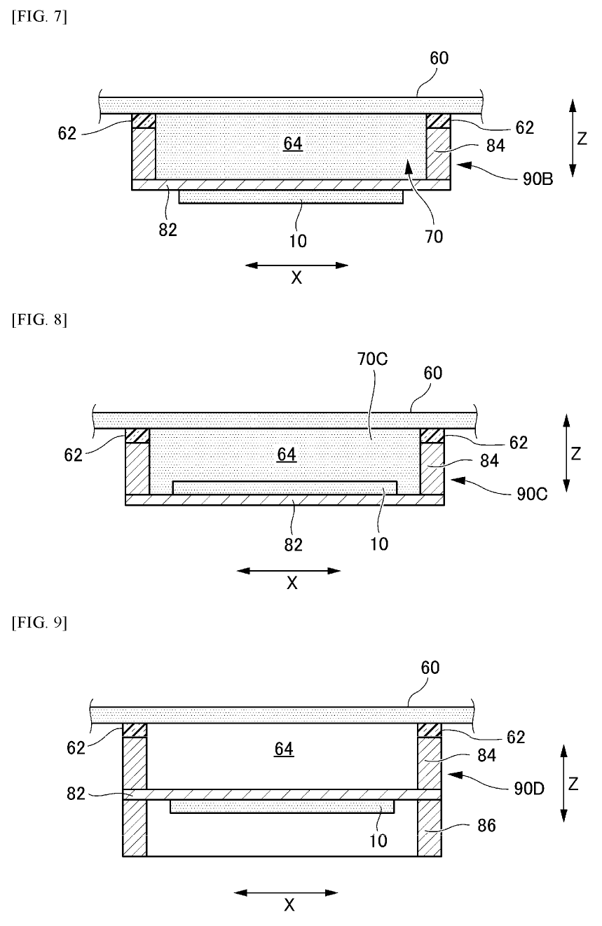

FIG. 7 is a cross-sectional view schematically showing a state that a vibration generating device 90B according to a third embodiment is attached to the display panel 60 (as an example of a vibration object member).

The vibration generating device 90B according to the third embodiment is different from the vibration generating device 90 according to the above-described first embodiment in that the piezoelectric actuator 10 is provided on the surface at the side (or the lower surface) opposite to the diaphragm 82 and a filling material 70 (also referred to as a vibration transmitting member) is filled inside the enclosed space 64.

The filling material 70 may be made of a rubber material, a resin (a foamed resin), silicone or the like.

Even with the vibration generating device 90B according to the third embodiment, it is possible to achieve the effects similar to those of the vibration generating device 90 according to the above-described first embodiment. Further, with the vibration generating device 90B according to the third embodiment, since the filling material 70 is provided to increase a mass element, it is possible to control a vibration frequency to be lowered as compared with a case where the filling material 70 is not provided. Also, it is possible to improve vibration transmissibility.

As exemplified in FIG. 7, the filling material 70 is entirely filled inside the enclosed space 64. However, the filling material 70 may be partially filled inside the enclosed space 64.

FIG. 8 is a cross-sectional view schematically showing a state that a vibration generating device 90C according to a fourth embodiment is attached to the display panel 60 (as an example of a vibration object member).

The vibration generating device 90C according to the fourth embodiment is different from the vibration generating device 90 according to the above-described first embodiment in that a filling material 70C is filled inside the enclosed space 64.

Like the filling material 70 according to the above-described third embodiment, the filling material 70C may be made of a rubber material, a resin (a foamed resin), silicone or the like.

Even with the vibration generating device 90C according to the fourth embodiment, it is possible to achieve the effects similar to those of the vibration generating device 90 according to the above-described first embodiment. Further, with the vibration generating device 90C according to the fourth embodiment, since the filling material 70C is provided to increase a mass element, it is possible to control a vibration frequency to be lowered as compared with a case where the filling material 70 is not provided. Also, it is possible to improve vibration transmissibility. In addition, it is possible to alleviate dropping impact and the like to improve reliability.

FIG. 9 is a cross sectional view schematically showing a state that a vibration generating device 90D according to a fifth embodiment is attached to the display panel 60 (as an example of a vibration object member).

The vibration generating device 90D according to the fifth embodiment is different from the vibration generating device 90 according to the above-described first embodiment in that the piezoelectric actuator 10 is provided on the surface at the side (or the lower surface) opposite to the diaphragm 82 and a second frame body 86 is added.

The second frame body 86 is provided on the side opposite to the frame body 84. That is, the second frame body 86 extends along the outer peripheral portion of the diaphragm 82 on the lower surface of the diaphragm 82. Like the frame body 84, the second frame body 86 is fixed to the outer peripheral portion of the diaphragm 82.

Even with the vibration generating device 90D according to the fifth embodiment, it is possible to achieve the effects similar to those of the vibration generating device 90 according to the above-described first embodiment. Further, with the vibration generating device 90D according to the fifth embodiment, since the second frame body 86 is provided to increase a mass of vibrating body (that is, since a mass element is increased), it is possible to increase vibration strength to be transmitted to the display panel 60.

It should be noted that the fifth embodiment may be combined with any one of the second to fourth embodiments as described above. That is, in the second to fourth embodiments as described above, the second frame body 86 may also be provided.

### REFERENCE SIGNS LIST

6 . . . electronic equipment;
10 . . . piezoelectric actuator;
11 . . . piezoelectric element;
60 . . . display panel;
62 . . . joining member;
64 . . . enclosed space;
66 . . . housing;
68 . . . electronic circuit;
70 . . . filling material;
70C . . . filling material;
82 . . . diaphragm;
84 . . . frame body;
86 . . . second frame body;
90 . . . vibration generating device;
90A . . . vibration generating device;
90B . . . vibration generating device;
90C . . . vibration generating device;
90D . . . vibration generating device;
110 . . . piezoelectric layer;
112 . . . internal electrode layer;
114 . . . surface electrode;
116 . . . side electrode;
621 . . . substrate layer; and
622 . . . joining layer.

1. A vibration generating device for non-acoustic applications, comprising:
a piezoelectric element;
a diaphragm attached to the piezoelectric element on a first side in a first direction; and
a first frame body provided along an outer peripheral portion of the diaphragm to transmit vibration of the diaphragm to a vibration object member,
wherein the first frame body is connectable to the vibration object member in such a manner that the first frame body, the diaphragm and the vibration object member form an enclosed space.

2. The vibration generating device according to claim 1, wherein the first frame body is provided along an outer peripheral portion on a surface at a second side of the diaphragm opposite to the first side in the first direction and is connected to the vibration object member on the second side in the first direction.

3. The vibration generating device according to claim 2, further comprising a second frame body provided along an outer peripheral portion on the surface of the diaphragm on the first side in the first direction.

4. The vibration generating device according to claim 1, further comprising a joining member provided between the first frame body and the vibration object member, the joining member including a viscoelastic body.

5. The vibration generating device according to claim 4, wherein the joining member includes a substrate layer and joining layers made of a viscoelastic body on both sides of the substrate layer in the first direction.

6. The vibration generating device according to claim 4, wherein the joining member is larger than the first frame body in a cross-sectional shape obtained by cutting along a plane having a normal vector in the first direction.

7. The vibration generating device according to claim 1, further comprising a vibration transmitting member provided in the enclosed space, the vibration transmitting member including at least one of a rubber material, a resin material and a silicone material and coming into contact with the diaphragm and the vibration object member in the first direction.

8. The vibration generating device according to claim 1, wherein the piezoelectric element has a bimorph structure or an unimorph structure.

9. An electronic equipment comprising:
a vibration generating device according to claim 1;
a vibration object member; and
an electronic circuit for driving the vibration generating device.

10. The electronic equipment according to claim 9, wherein the vibration object member is a display panel.
